(19) United States
(12) Patent Application Publication
(10) Pub. No.: US 2007/0221973 A1
(43) Pub. Date: Sep. 27, 2007

(54) SOLID-STATE IMAGING DEVICE AND METHOD FOR MANUFACTURING THE SAME

(75) Inventors: Hiroki Nagasaki, Kyoto (JP); Shouzi Tanaka, Nara (JP); Motonari Katsuno, Kyoto (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/688,536

(22) Filed: Mar. 20, 2007

(30) Foreign Application Priority Data
Mar. 24, 2006 (JP) JP2006-083420
Jan. 22, 2007 (JP) JP2007-011742

(51) Int. Cl. H01L 31/113; H01L 31/062

(52) U.S. Cl. 257/292

(57) ABSTRACT

A solid-state imaging device includes: a plurality of photodiodes arranged in a matrix on a semiconductor substrate 1 for storing a signal charge converted from incident light; MOS transistors for reading the signal charge stored in the photodiode, an element isolation region for isolating the photodiode from the MOS transistors, an implanted isolation layer formed below the element isolation region, and an impurity region surrounding the photodiode, the sides and bottom of the element isolation region and the implanted isolation layer. The implanted isolation layer covers the sides and bottom of the element isolation region. The solid-state imaging device can efficiently suppress the sensitivity degradation caused by the outflow of electric charge.

### BACKGROUND OF THE INVENTION

1. Field of the Invention

The present invention relates to a solid-state imaging device in which an element isolation region is formed by trenching a semiconductor substrate using STI (Shallow Trench Isolation) and a method for manufacturing the same.

2. Description of Related Art

Recently, solid-state imaging devices having amplifier MOS transistors have been attracting a lot of attention. The solid-state imaging device has a high sensitivity, in which a signal detected by a photodiode is amplified by a MOS transistor in each pixel.

A solid-state imaging device having amplifier MOS transistors will be described below with reference to JP 2004-266159A.

FIG. 8 is a circuit diagram illustrating the configuration of a solid-state imaging device having amplifier MOS transistors. This solid-state imaging device includes a plurality of pixel cells 2 arranged in a matrix on a semiconductor substrate 1. The pixel cells 2 each have a photodiode 3 for storing a signal charge converted from incident light. In order to read out and output the signal charge stored in the photodiode 3, the pixel cells 2 each also have a transfer transistor 4, an amplifying transistor 5 and a reset transistor 6. The amplifying transistor 5 amplifies the signal charge read by the transfer transistor 4. The reset transistor 6 resets the signal charge read by the transfer transistor 4.

In order to control the operation of each pixel cell 2, a vertical drive circuit 7, a row signal storage unit 8, a horizontal drive circuit 9 and a load transistor group 10 are provided. A plurality of reset transistor control lines 11 are connected to the vertical drive circuit 7 with a certain spacing between adjacent reset transistor control lines along the horizontal direction, and connected to the gate of the reset transistor 6 formed in each pixel cell 2. Similarly, a plurality of vertical selection transistor control lines 12 also are connected to the vertical drive circuit 7 with a certain spacing between adjacent vertical selection transistor control lines along the horizontal direction, and connected to the gate of a vertical selection transistor 13 formed in each pixel cell 2. The vertical selection transistor control lines 12 determine from which row to read out a signal.

The sources of the vertical selection transistors 13 are connected to vertical signal lines 14. One end of each vertical signal line 14 is connected to the load transistor group 10. The other end of each vertical signal line 14 is connected to the row signal storage unit 8. The row signal storage unit 8 includes a switch transistor (not shown) for storing signals for one row. The row signal storage unit 8 is connected to the horizontal drive circuit 9.

FIG. 9 is a plan view illustrating the regions of a photodiode 3, a transfer transistor 4, an amplifying transistor 5 and a reset transistor 6 formed in a solid-state imaging device configured as shown in FIG. 8. A transfer gate 4a is placed between a photodiode 3 and a floating diffusion layer (detector capacitance portion) 15. MOS transistors 16 including an amplifying transistor 5 and a reset transistor 6 are formed adjacent to the photodiode 3. Each of the MOS transistors 16 has a gate electrode 22 formed on an n-type semiconductor substrate, a source 23 formed at one side of the gate electrode 22 and a drain 24 formed at the other side of the same. The following description applies also to the amplifying transistor 5 and the reset transistor 6, and thus these transistors are described as the MOS transistors 16 below.

FIG. 10 shows a cross-sectional view taken along the line A-A of FIG. 9. As can be seen from this cross-sectional structure, a p-type well 1a is formed as an impurity region on a surface region of an n-type semiconductor substrate 1. In the p-type well 1a, photodiodes 3 and the MOS transistors 16 are formed. The photodiodes 3 are buried-type pnp photodiodes, each including a surface shield layer 20 formed on a surface of an n-type semiconductor substrate 1 and a storage photodiode layer 21 formed below the surface shield layer 20.

An element isolation region 25 is formed between the photodiode 3 and the MOS transistor 16 by trenching the n-type semiconductor substrate 1 using STI (Shallow Trench Isolation) so as to isolate the photodiode 3 from the MOS transistor 16. Another element isolation region 26 is formed to isolate the adjacent photodiodes 3 included in adjacent pixel cells 2. A deep implanted isolation layer 29 is formed below the element isolation regions 25 and 26.

The interface between the n-type semiconductor substrate 1 and the p-type well 1a is at a depth of, for example, 2.8 micrometers (μm). The n-type semiconductor substrate 1 has an impurity concentration of about 2×10¹⁴ cm⁻³. The p-type well 1a has an impurity concentration of about 1×10¹⁵ cm⁻³.

The electric charge stored in the photodiode 3 is discharged directly into the semiconductor substrate 1 as shown by the arrow Q in FIG. 10. This well structure also can prevent the electric charge generated at a deep portion of the substrate from reaching the photodiode and 3 and the MOS transistor 16.

The conventional solid-state imaging device as described above has the following problems. A first problem is that the saturation charge amount of photodiodes decreases by the outflow of electric charge from a photodiode to a MOS transistor or by the outflow of electric charge from a photodiode to another photodiode in an adjacent pixel cell, whereby color mixing occurs and sensitivity decreases.

A second problem is that, although the electric charge generated in a position shallower than a dividing row 30 formed at a depth of about 1.8 μm nearly in the center between the bottom of the p-type well 1a and that of the storage photodiode layer 21 reaches the photodiode 3, the electric charge generated in a position deeper than the dividing row 30 does not reach the photodiode 3, whereby sensitivity degrades.

### SUMMARY OF THE INVENTION

Therefore, with the foregoing in mind, it is an object of the present invention to provide a solid-state imaging device capable of efficiently suppressing the sensitivity degradation caused by the outflow of electric charge and to provide a method for manufacturing the solid-state imaging device.

The solid-state imaging device of the present invention includes: a plurality of photodiodes arranged in a matrix on a semiconductor substrate for storing a signal charge converted from incident light; MOS transistors for reading out the signal charge stored in the photodiode; an element isolation region for isolating the photodiode from the MOS transistors; an implanted isolation layer formed below the element isolation region; and an impurity region surrounding the photodiode, the sides and bottom of the element isolation region and the implanted isolation layer. In order to solve the problem, the implanted isolation layer covers the sides and bottom of the element isolation region.

The method for manufacturing a solid-state imaging device of the present invention is a method for manufacturing the solid-state imaging device configured as above. The method includes the steps of forming a trench by trenching the semiconductor substrate so as to form the element isolation region; implanting an impurity obliquely into a sidewall of the trench and then vertically into a bottom of the trench so as to form the implanted isolation layer; forming the element isolation region in the trench after the impurity implanting step; and forming the photodiode and one or more of the MOS transistors after the element isolation region forming step.

### BRIEF DESCRIPTION OF THE DRAWINGS

FIG. 1 is a cross-sectional view showing a relevant portion of a solid-state imaging device according to a first embodiment of the present invention.

FIGS. 2A to 2J are cross-sectional views illustrating the steps of a method for manufacturing the solid-state imaging device of the first embodiment.

FIGS. 3A to 3E are enlarged cross-sectional views of relevant portions of FIGS. 2B to 2F, respectively.

FIG. 4 is a cross-sectional view illustrating another configuration of a high concentration implanted isolation layer of FIG. 3E.

FIG. 5 is a schematic plan view illustrating a configuration of a pixel cell of a solid-state imaging device according to a second embodiment of the present invention.

FIG. 6A is a schematic plan view of a floating diffusion layer of the solid-state imaging device of the second embodiment showing the shape of the floating diffusion layer and a portion thereof on which stress concentrates.

FIG. 6B is a schematic plan view of a floating diffusion layer of a solid-state imaging device of a comparative example showing the shape of the floating diffusion layer and a portion thereof on which stress concentrates.

FIG. 7 is a schematic plan view showing a part of a pixel cell of a conventional solid-state imaging device.

FIG. 8 is a circuit diagram showing a configuration of a MOS-type solid-state imaging device.

FIG. 9 is a plan view showing a configuration of a region of a photodiode and a MOS transistor formed in the solid-state imaging device of FIG. 8.

FIG. 10 is a cross-sectional view taken along the line A-A of FIG. 9.

### DETAILED DESCRIPTION OF THE INVENTION

The solid-state imaging device of the present invention includes a photodiode, a MOS transistor for reading out a signal charge stored in the photodiode, and an element isolation region for isolating the photodiode from the MOS transistor. An implanted isolation layer is formed below the element isolation region. An impurity region is formed such that it surrounds the photodiode, the element isolation region as well as the sides and bottom of the implanted isolation layer. The implanted isolation layer covers the sides and bottom of the element isolation layer. Thereby, the outflow of electric charge from the photodiode to the MOS transistor is effectively prevented. As a result, a solid-state imaging device having an excellent sensitivity can be obtained.

In the solid-state imaging device of the present invention configured as above, the element isolation region can be formed by STI (Shallow Trench Isolation).

Alternatively, the following configuration can be employed. A P-type well is formed on a semiconductor substrate. The MOS transistor has a source and a drain formed in the P-type well. An impurity having a conductivity type opposite to that of the source and drain of the MOS transistor is implanted into the implanted isolation layer

The element isolation region can be formed so as to isolate the photodiodes from each other. The implanted isolation layer can be formed so as to prevent the outflow of electric charge from the photodiode included in one pixel cell to the photodiode included in another pixel cell adjacent thereto.

Preferably, the implanted isolation layer has an impurity concentration higher than that of the impurity region covering the sides of the element isolation region.

The implanted isolation layer can be formed in a position such that it does not overlap an adjacent photodiode.

The photodiode includes a surface shield layer formed on the surface of the semiconductor substrate and a storage photodiode layer formed below the surface shield layer. The implanted isolation layer can have an impurity concentration higher than that of the storage photodiode layer.

The solid-state imaging device may have a structure in which multiple pixels are included in one cell.

In the method for manufacturing the solid-state imaging device of the present invention having the above configuration, the semiconductor substrate may include an N-type substrate, and a P-type well surrounding a photodiode formed on a surface region of the N-type substrate and the sides and bottom of the element isolation region and the implanted isolation layer.

When the solid-state imaging device has a structure in which multiple pixels are included in one cell (hereinafter referred to as “multiple-pixels-in-one-cell structure”), in the step of implanting an impurity into the sidewall of the trench formed around the photodiode included in each pixel, it is preferable to implant an impurity from a direction including a horizontal direction component perpendicular to the sidewall of the trench.

When the sidewall of the trench includes a portion that is neither vertical or horizontal relative to the photodiode, it is preferable to implant an impurity from multiple directions including a horizontal direction component perpendicular to the sidewall of the trench.

Hereinafter, the present invention will be described by way of illustrative embodiments with reference to the drawings.

### Embodiment 1

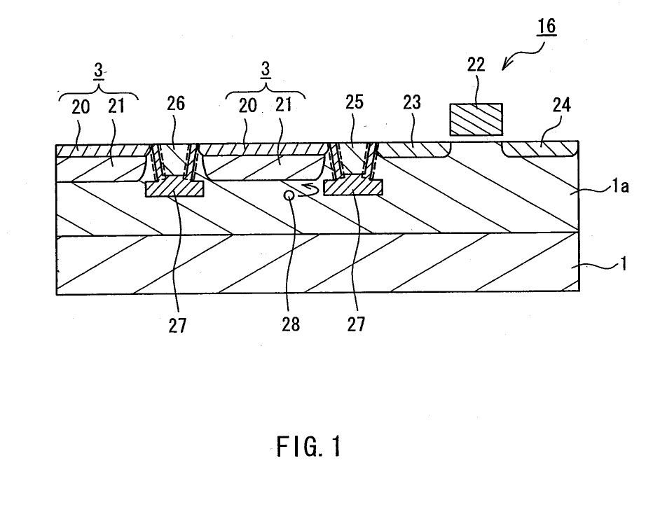

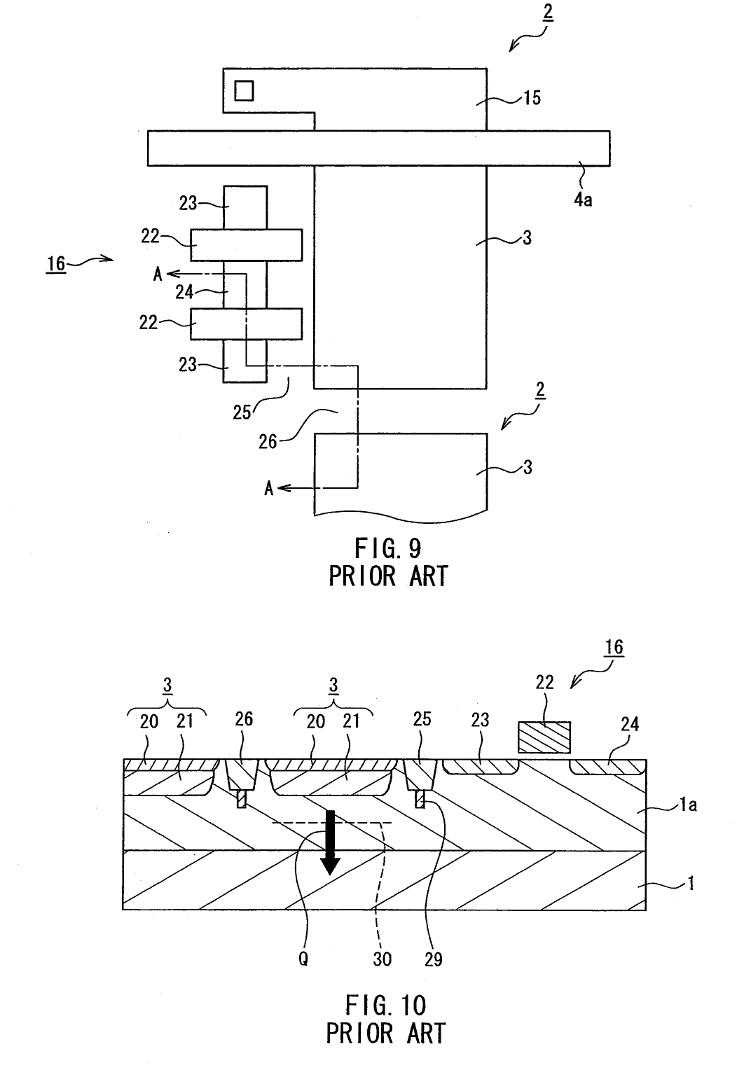

The circuit diagram illustrating an overall configuration of a solid-state imaging device according to a first embodiment of the present invention is the same as that shown in FIG. 8. The planar structure of the solid-state imaging device according to this embodiment showing a region including a photodiode 3 and a MOS transistor is the same as that of the conventional one shown in FIG. 9. The solid-state imaging device according to this embodiment is characterized by the cross-sectional structure shown in FIG. 1. In FIG. 1, the basic cross-sectional structure is the same as that of a conventional solid-state imaging device shown in FIG. 10, and thus the same reference numbers are given to the same elements. FIG. 1 is a cross-sectional view taken along the line A-A of FIG. 9, which shows a plan view illustrating a region of a photodiode 3 and a MOS transistor 16, as in the conventional example shown in FIG. 10.

A p-type well 1a is formed as an impurity region in a surface region of an n-type semiconductor substrate 1. In the p-type well 1a, photodiodes 3 and a MOS transistor 16 are formed. The photodiodes 3 are buried-type pnp photodiodes, each including a surface shield layer 20 formed in a surface of the n-type semiconductor substrate 1 and a storage photodiode layer 21 formed below the surface shield layer 20. The surface shield layer 20 has a conductivity type opposite to that of the n-type semiconductor substrate 1. The storage photodiode layer 21 has the same conductivity type as that of the n-type semiconductor substrate 1. The surface shield layer 20 is formed to a depth of about 0.2 μm. The storage photodiode layer 21 is formed to a depth of about 0.8 μm.

The MOS transistor 16 is formed adjacent to the photodiode 3. The MOS transistor 16 has a gate electrode 22 formed on the n-type semiconductor substrate 1, a source 23 formed at one side of the gate electrode 22 and a drain 24 formed at the other side of the same. According to an example of this first embodiment, the source 23 and the drain 24 have a depth of about 0.1 μm.

An element isolation region 25 is formed between the photodiode 3 and the MOS transistor 16 by trenching the n-type semiconductor substrate 1 using STI so as to isolate the photodiode 3 from the MOS transistor 16. Another element isolation region 26 similar to the element isolation region 25 is formed so as to isolate the photodiode 3 from another photodiode 3 included in an adjacent pixel cell 2.

The element isolation regions 25 and 26 are formed to a depth of about 300 nanometers (nm). With progress in microfabrication of transistors, the element isolation regions 25 and 26 also may be formed shallower. The reason is as follows. With progress in the microfabrication, the width of the element isolation regions is decreased sharply. If the element isolation regions are formed by trenching deeply into the substrate, the aspect ratio will increase, and thus the trenches will not be filled with oxidation film. On the sides of and below the element isolation regions 25 and 26, a high concentration implanted isolation layer 27 is formed along a direction vertical to the surface of the n-type semiconductor substrate 1. The high concentration implanted isolation layer 27 serves to prevent the outflow of electric charge from the photodiode 3 to the MOS transistor 16 as well as to prevent the outflow of electric charge from the photodiode 3 to another photodiode 3 included in an adjacent pixel cell 2.

The n-type semiconductor substrate 1 has an impurity concentration of 1.0×10¹⁴ cm⁻³. The p-type well 1a has an impurity concentration of 1.0×10¹⁵ cm⁻³. The sides of the element isolation region 25, 26 have an impurity concentration of 2.0×10¹⁷ cm⁻³. The high concentration implanted isolation layer 27 has an impurity concentration of 1.0×10¹⁸ cm⁻³ or higher. In other words, the impurity concentration of the high concentration implanted isolation layer 27 is higher than that of the sides of the element isolation region 25, 26. The high concentration implanted isolation layer 27 can be extended as long as it does not overlap the adjacent photodiode 3.

A method of discharging an electric charge for the solid-state imaging device according to the first embodiment will be described. First, electrons 28 serving as a signal charge overflowing from the photodiode 3 are released into a p-type neutral region where a plurality of positive holes exist. The electrons 28 released from the photodiode 3 into the p-type neutral region have a long lifetime. Thus, the electrons migrate randomly in a region where no electric field is applied without being recombined with the positive holes.

Part of the electrons 28 released from the photodiode 3 into the p-type neutral region flows into the n-type semiconductor substrate 1. Another part of the released electrons 28 flows into the adjacent photodiode 3 or the MOS transistor 16. Whether the electrons flow into the n-type semiconductor substrate 1, the adjacent photodiode 3 or MOS transistor 16 is a matter of probability. This method of discharging an electric charge is called “bipolar action mode”.

In order to reduce the probability of the electrons flowing into the adjacent photodiode 3 or MOS transistor 16, the high concentration implanted isolation layer 27 is necessary. To reduce this probability, the high concentration implanted isolation layer 27 preferably has an impurity concentration higher than that of the p-type well 1a.

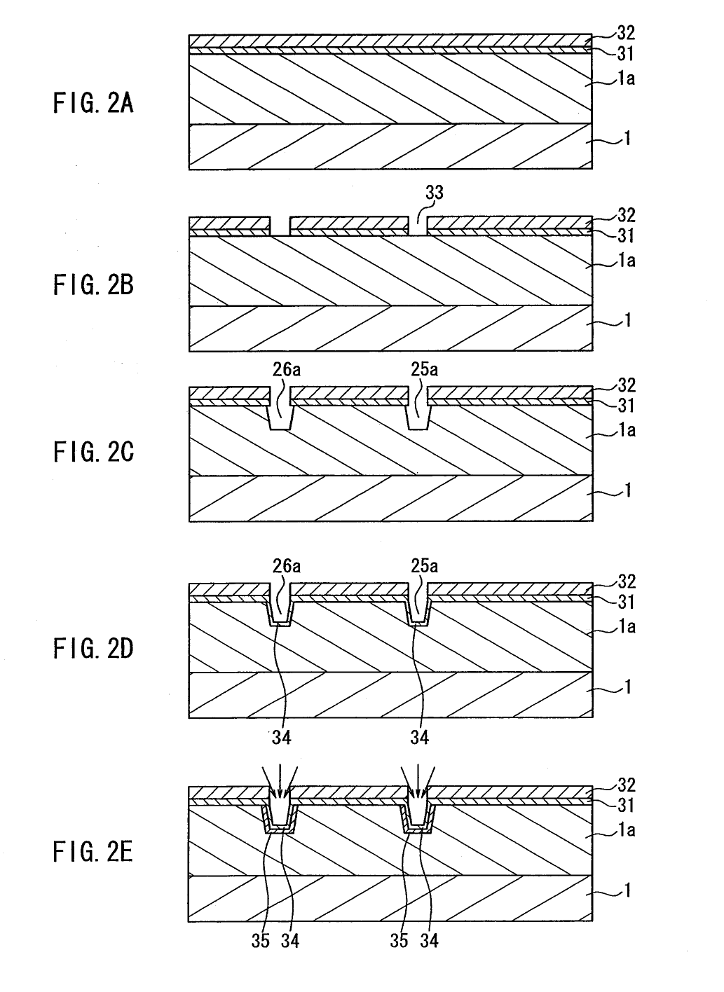

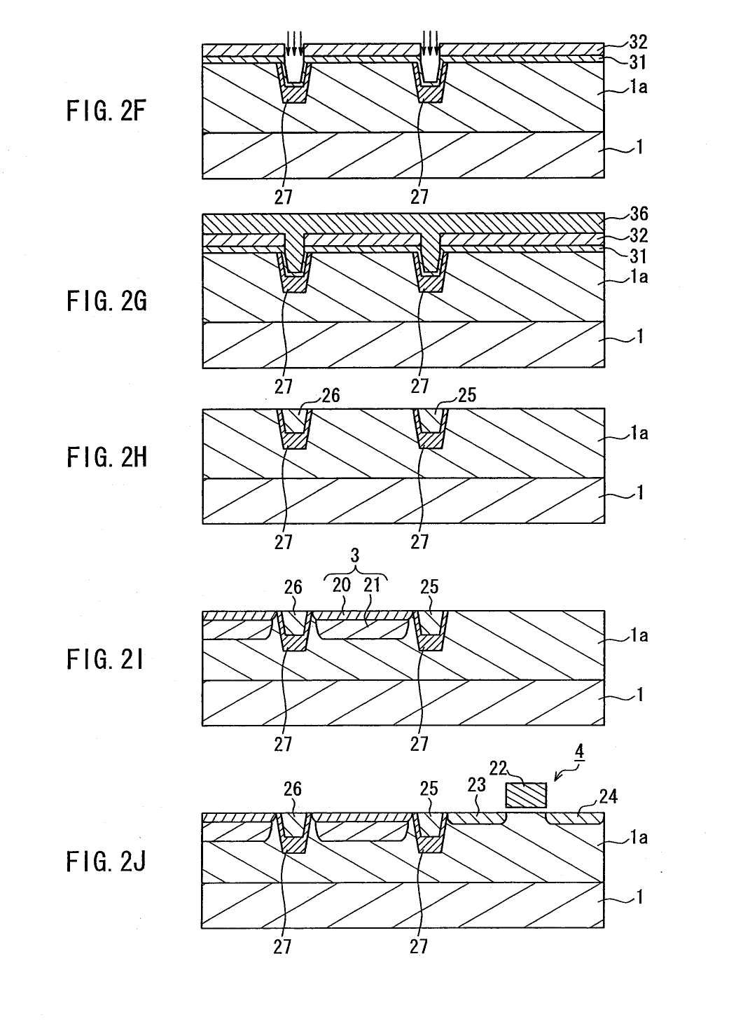

A method for manufacturing the solid-state imaging device according to this first embodiment of the present invention will be described below with reference to FIGS. 2A to 2J.

As shown in FIG. 2A, a 20 nm thick silicon oxide film (SiO₂ film) 31 is deposited onto a main surface of a p-type well 1a formed in an n-type semiconductor substrate 1 by thermal oxidation or CVD (Chemical Vapor Deposition). A 160 nm thick silicon nitride film 32 is then deposited onto the formed SiO₂ film 31 by CVD.

Subsequently, a resist pattern (not shown) having openings corresponding to the element isolation regions 25 and 26 is provided on the silicon nitride film 32 by a well-known method. Using this resist pattern as a mask, gaps 33 are formed by dry etching in the SiO₂ film 31 and the silicon nitride film 32 as shown in FIG. 2B. Further, as shown in FIG. 2C, trenches 25a and 26a for forming the element isolation regions 25 and 26, respectively, are formed in a surface region of the p-type well 1a. The trenches 25a and 26a have a depth of, for example, about 0.3 μm.

As shown in FIG. 2D, a 20 nm thick silicon oxide film (SiO₂ film) 34 is formed, by thermal oxidation, on the surface of the p-type well 1a exposed by the formation of the trench 25a, 26a. Subsequently, ions are implanted into the inside of the face of the trench 25a, 26a at a low accelerating voltage as shown in FIG. 2E. Specifically, boron (B) ions are implanted, for example, from four different directions at 30 kiloelectron volts (KeV) with a dose of 3.2×10¹³/cm². Thereby, a P⁺-type inner film 35 is formed in the inside of the face of the trench 25a, 26a.

As shown in FIG. 2F, boron (B) ions are further implanted into the inside of the face of the trench 25a, 26a covered with the P⁺-type inner film 35 from a vertical direction, for example, at an accelerating voltage of 30 KeV with a dose of 1.0×10¹⁴/cm². Thereby, a high concentration implanted isolation layer 27 covering the sides and the bottom of the trench 25a, 26a is formed.

The trench 25a, 26a is then filled with a SiO₂ film 36 by CVD as shown in FIG. 2G. Subsequently, the SiO₂ films 31 and 36 and the silicon nitride film 32 formed above the surface of the n-type semiconductor substrate 1 are removed as shown in FIG. 2H. In this manner, element isolation regions 25 and 26 are formed.

Subsequently, a photodiode 3 including a surface shield layer 20 and a storage photodiode layer 21 is formed as shown in FIG. 2I. Further, a MOS transistor 16 including a gate electrode 22, a source 23 and a drain 24 is formed as shown in FIG. 2J.

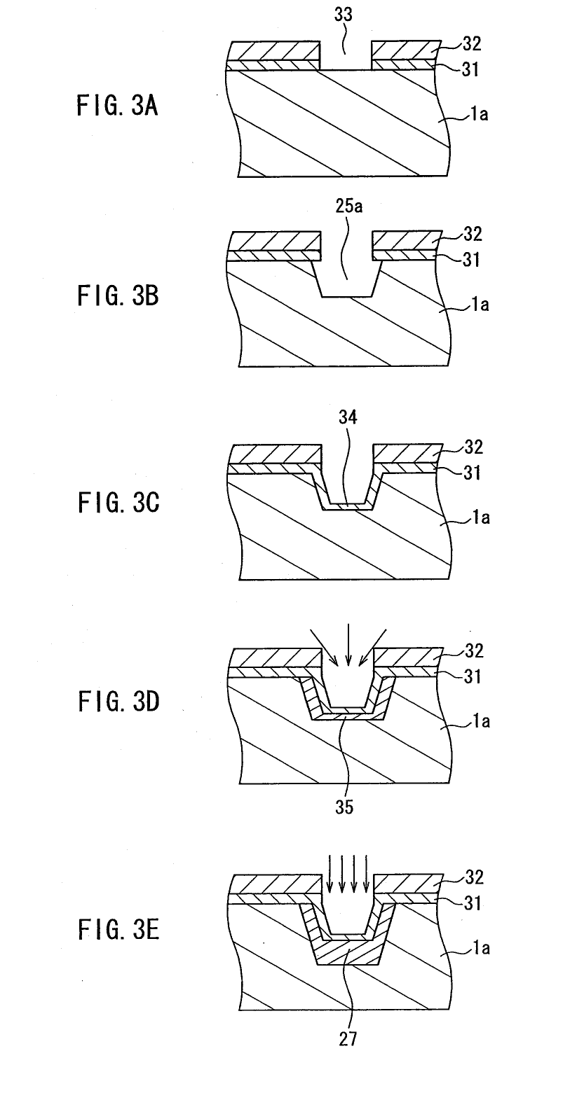

A detailed description of a method for forming the high concentration isolation implanted isolation layer 27 below the element isolation region 25, 26 will be given with reference to FIGS. 3A to 3E. FIGS. 3A to 3E are enlarged cross-sectional views of relevant portions of FIGS. 2B to 2F, respectively.

As shown in FIG. 3A, a gap 33 is formed in an SiO₂ film 31 and a silicon nitride film 32 by dry etching using a resist pattern (not shown) having openings corresponding to an element isolation region 25. As shown in FIG. 3B, a trench 25a for forming the element isolation region 25 is then formed by trenching an n-type semiconductor substrate 1 (i.e., p-type well 1a) by means of etching. Subsequently, as shown in FIG. 3C, a silicon oxide film (SiO₂ film) 34 is formed by thermal oxidation on the surface of the p-type well 1a exposed by the formation of the trench 25a.

Ions are then implanted into the inside of the face of the formed trench 25 at a low accelerating voltage as shown in FIG. 3D. Specifically, ions are implanted from four different directions at an accelerating voltage of not less than 20 KeV and not greater than 50 KeV with a dose of not less than 3.0×10¹³ cm⁻² and not greater than 1.0×10¹⁴ cm⁻². Thereby, a P⁺-type inner film 35 is formed in the inside of the face of the trench 25a.

Another ion implantation is performed as shown in FIG. 3E by implanting ions to the bottom of the trench 25a covered with the P⁺-type inner film from a vertical direction at an accelerating voltage of not less than 20 KeV and not greater than 1 megaelectron volt (MeV) with a dose of not less than 3.0×10¹³ cm⁻² and not greater than 1.0×10¹⁴ cm⁻². As a result, a high concentration implanted isolation layer 27 having an impurity concentration of 1.0×10¹⁸ cm⁻³ or higher is formed below the trench 25a.

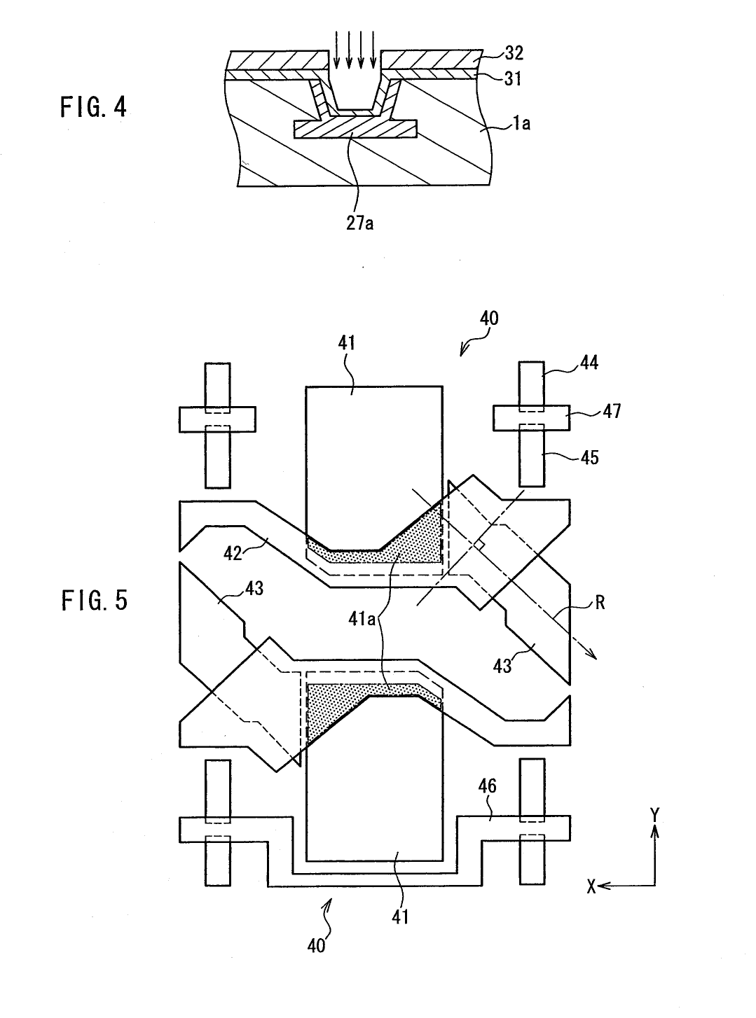

The high concentration implanted isolation layer 27 shown in FIG. 3E can be extended, as the high concentration implanted isolation layer 27a shown in FIG. 4, as long as the high concentration implanted isolation layer 27 does not overlap the adjacent photodiode.

In the solid-state imaging device as described above, as shown in FIG. 1, the signal charge 28 converted from incident light by the photodiode 3 and stored in the storage photodiode layer 21 is prevented, by the high concentration implanted isolation layer 27, from flowing into the transfer transistor 4 and the adjacent photodiode 3.

The high concentration implanted isolation layer 27 also prevents the electrons 28 serving as the signal charge stored in the storage photodiode layer 21 from flowing into the MOS transistor 16, whereby the saturation signal charge of the photodiode 3 increases. The high concentration implanted isolation layer 27 further prevents the electrons 28 stored in the storage photodiode layer 21 from flowing into the adjacent photodiode 3, whereby color mixing can be suppressed and a solid-state imaging device having excellent color reproduction can be obtained.

As described above, in the solid-state imaging device according to this embodiment, a high concentration implanted isolation layer covering the sides and bottom of an element isolation region is formed so as to prevent the electric charge from flowing from the photodiode into the MOS transistor. This prevents the outflow of electric charge from the photodiode to the MOS transistor. Consequently, a solid-state imaging device having an excellent sensitivity can be obtained.

In addition, another high concentration implanted isolation layer covering the sides and bottom of another element isolation region is formed so as to prevent the electric charge from flowing from a photodiode to another photodiode included in an adjacent pixel cell. This prevents the outflow of electric charge from a photodiode to another photodiode included in an adjacent pixel cell. Consequently, a solid-state imaging device having an excellent sensitivity can be obtained.

### Embodiment 2

A solid-state imaging device according to a second embodiment of the present invention will be described with reference to FIG. 5. FIG. 5 is a plan view schematically illustrating a configuration of a pixel cell 40, which constitutes a feature of the solid-state imaging device according to the second embodiment.

As shown in FIG. 5, the solid-state imaging device according to this embodiment has a multiple-pixels-in-one-cell structure. According to the configuration shown in FIG. 5, a structure in which two pixels are included in one cell is employed. Each pixel cell 40 includes a photodiode 41 formed on a semiconductor substrate, a transfer gate 42 for transferring an electric charge stored in the photodiode 41 formed such that it extends above and across a portion of the photodiode 41, and a floating diffusion layer (detector capacitance portion) 43 for storing the electric charge transferred by the transfer gate 42.

Similarly to the pixel cells 2 of the solid-state imaging device of the first embodiment, the pixel cell 40 further includes a source region 44, a drain region 45, a reset gate 46 and an amplifying gate 47. In each pixel cell 40, element isolation regions for isolating the regions having the above-described functions from each other are formed.

In this multiple-pixels-in-one-cell structure, the border between the active region of the photodiode 41 and the element isolation region may be formed in an oblique direction (see, for example, a floating diffusion layer 43 of FIG. 5). In this case also, it is preferable to distribute the impurity uniformly into the sidewall of the element isolation region. This can be achieved by implanting the impurity from multiple directions including a horizontal direction perpendicular to the sidewall of each element isolation region.

The electric connection between the transfer gates 42 of the adjacent pixel cells 40 is effected by wiring by extending the transfer gates 42 outside the regions of the photodiodes 41. In this embodiment, the transfer gates 42 include such extended portions for wiring. Alternatively, the electric connection between the transfer gates 42 may be effected by using metal wires arranged thereon and contacts.

The transfer gate 42 is formed to be oblique relative to the photodiode 41 and the floating diffusion layer 43 in the region where the electric charge stored in the photodiode 41 is read out by the floating diffusion layer 43. The electric charge stored in the photodiode 41 is read out by the floating diffusion layer 43 that is positioned either in the right lower oblique direction or left upper oblique direction. In other words, in the solid-state imaging device according to this second embodiment, when the electric charge stored in the photodiode 41 is read out by the floating diffusion layer 43, the electric charge is read out in a direction substantially perpendicular to the extending direction of the transfer gate 42, more specifically, in a direction shown by the dash dotted arrow R in FIG. 5.

In the solid-state imaging device according to this embodiment, the photodiode 41 has a shape substantially symmetric with respect to vertical and horizontal directions (X axis direction and Y axis direction) such as a polygonal shape or substantially rectangular shape. This is because it can reduce variations in the distribution of electric charge generated in the photodiode 41 in both vertical and horizontal directions (X axis direction and Y axis direction), whereby the degradation of shading characteristics of the solid-state imaging device can be prevented.

Furthermore, in the solid-state imaging device of this embodiment, in each pixel cell 40, the wiring connecting the transfer gate 42 and the reset gate 46 as well as the wiring connecting the transfer gate 42 and the amplifying gate 47 are formed to have a nonlinear shape. Thereby, the percentage of the area of the element isolation region can be reduced, and that of the area of the photodiode 41 in the pixel cell 40 can be increased. In FIG. 5, the reference number 41a indicates an overlapping region where the photodiode 41 and the transfer gate 42 overlap with each other. The overlapping region is a non-salicide region through which optical signals pass.

The solid-state imaging device according to the second embodiment configured as above has the following two characteristics.

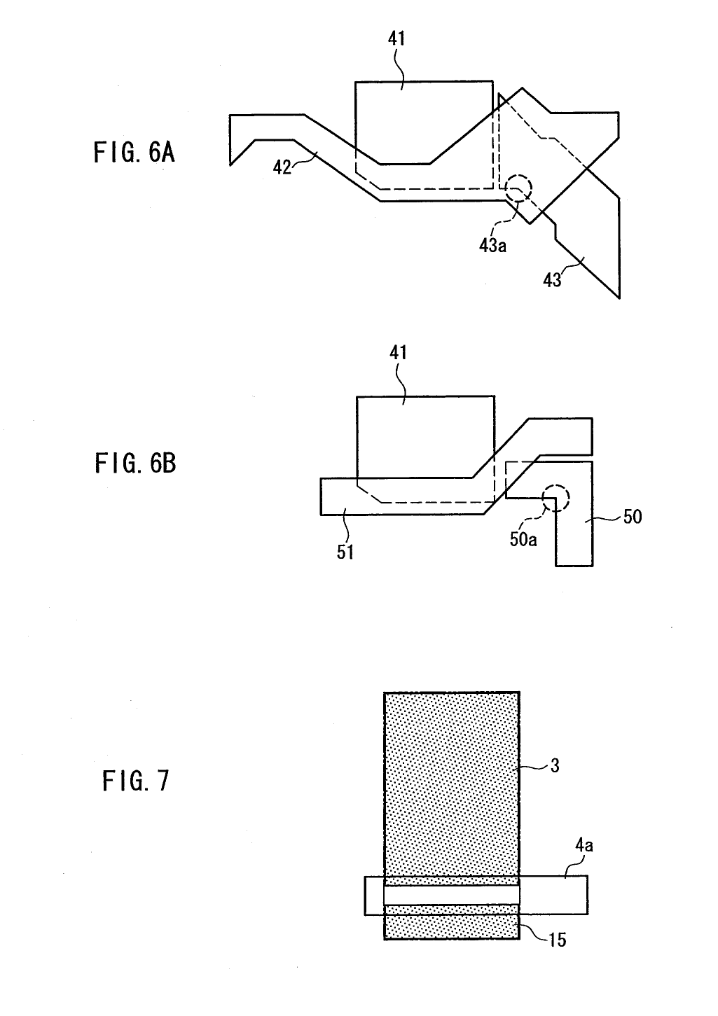

(1) A first characteristic is that the transfer gate 42 is formed in an oblique direction (in an oblique direction relative to X and Y axis directions) in the region connecting the floating diffusion layer 43 and the photodiode 41 as shown in FIG. 5. This suppresses noise (leakage) caused by defects, and thus an excellent image can be provided. A detailed description will be given with reference to FIGS. 6A and 6B. FIG. 6A schematically shows a configuration of the floating diffusion layer 43 of the solid-state imaging device of the second embodiment. FIG. 6B schematically shows a floating diffusion layer 50 and a transfer gate 51 of a solid-state imaging device of a comparative example.

As shown in FIG. 6B, in the solid-state imaging device of a comparative example, the floating diffusion layer 50 has a bending region 50a in which adjacent sides intersect at substantially a right angle, and stress may concentrate on this bending region 50a. Accordingly, in the floating diffusion layer 50 having such a bending region 50a in which adjacent sides intersect at substantially a right angle, defects may occur in this bending region 50a, causing noise (leak current).

In contrast, in the bending region 43a of the floating diffusion layer 43 of the solid-state imaging device of this embodiment, adjacent sides intersect at an obtuse angle as shown in FIG. 6A, and therefore stress hardly concentrates on this bending region 43a. Accordingly, in the solid-state imaging device of this embodiment, it is possible to minimize the occurrence of noise (leak current).

(2) A second characteristic is that the transfer gate 42 is arranged in an oblique direction in the cell having the multiple-pixels-in-one-cell structure, whereby it is possible to obtain a gate length longer than that of a solid-state imaging device having a structure in which one pixel is included in one cell (hereinafter referred to as “one-pixel-in-one-cell structure”).

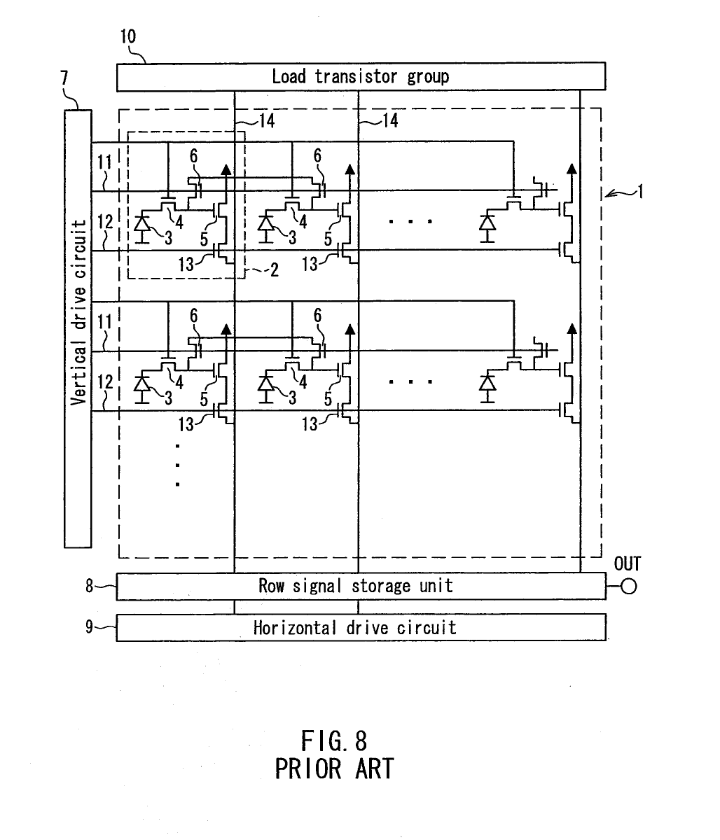

In the solid-state imaging device of Embodiment 1 (FIG. 7) or the comparative example (FIG. 6B) having the one-pixel-in-one-cell structure, for example, the gate width of the transfer gate 4a, 51 is determined by the relative position of the reset gate and the transfer gate 4a, 51. Accordingly, the gate width of the transfer gate 4a, 51 is determined depending on its minimum processing size as shown in FIG. 7 or 6B, and therefore it is difficult for the transfer gate 4a, 51 to have a sufficiently large gate width.

On the other hand, in the solid-state imaging device of this embodiment having the multiple-pixels-in-one-cell structure, the configuration as shown in FIG. 5 is employed, whereby the transfer gate 42 for the upper pixel cell 40 and the transfer gate 42 for the lower pixel cell 40 can be arranged symmetrically. Thereby, it is possible to increase the gate length of the transfer gates 42. Consequently, the electric charge can be transferred easily and efficiently from the photodiode 41 to the floating diffusion layer 43.

The high concentration implanted isolation layer can be formed not only below the element isolation region of the photodiode 3, but also below all the element isolation regions formed in the solid-state imaging device.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A solid-state imaging device comprising:
a plurality of photodiodes arranged in a matrix on a semiconductor substrate for storing a signal charge converted from incident light;
MOS transistors for reading out the signal charge stored in the photodiode;
an element isolation region for isolating the photodiode from the MOS transistors;
an implanted isolation layer formed below the element isolation region; and
an impurity region surrounding the photodiode, the sides and bottom of the element isolation region and the implanted isolation layer,
wherein the implanted isolation layer covers the sides and bottom of the element isolation region.

2. The solid-state imaging device according to claim 1,
wherein the element isolation region is formed by STI (Shallow Trench Isolation).

3. The solid-state imaging device according to claim 1,
wherein a P-type well is formed in the semiconductor substrate,
the MOS transistor comprises a source and a drain formed in the P-type well, and
an impurity having a conductivity type opposite to that of the source and the drain included in the MOS transistor is implanted into the implanted isolation layer.

4. The solid-state imaging device according to claim 1,
wherein the element isolation region is formed to isolate the photodiodes from each other, and
the implanted isolation layer is formed to prevent an outflow of electric charge from the photodiode included in one of the pixel cells to the photodiode included in another pixel cell adjacent thereto.

5. The solid-state imaging device according to claim 1,
wherein the implanted isolation layer has an impurity concentration higher than that of the impurity region formed on the sides of the element isolation region.

6. The solid-state imaging device according to claim 1,
wherein the implanted isolation layer is formed in a position such that it does not overlap adjacent photodiode.

7. The solid-state imaging device according to claim 1,
wherein the photodiode comprises a surface shield layer formed in a surface of the semiconductor substrate and a storage photodiode layer formed below the surface shield layer, and
the implanted isolation layer has an impurity concentration higher than that of the storage photodiode layer.

8. The solid-state imaging device according to claim 1,
wherein the solid-state imaging device has a structure in which multiple pixels are included in one cell.

9. A method for manufacturing a solid-state imaging device comprising: a plurality of photodiodes arranged in a matrix on a semiconductor substrate for storing a signal charge converted from incident light; MOS transistors for reading out the signal charge stored in the photodiode; an element isolation region for isolating the photodiode from the MOS transistors; an implanted isolation layer covering the sides and bottom of the element isolation region; and an impurity region surrounding the photodiode, the sides and bottom of the element isolation region and the implanted isolation layer, the method comprising the steps of:
forming a trench by trenching the semiconductor substrate so as to form the element isolation region;
implanting an impurity obliquely into a sidewall of the trench and then vertically into a bottom of the trench so as to form the implanted isolation layer;
forming the element isolation region in the trench after the impurity implanting step; and
forming the photodiode and one or more of the MOS transistors after the element isolation region forming step.

10. The method for manufacturing a solid-state imaging device according to claim 9,
wherein the semiconductor substrate comprises:
an N-type substrate,
a P-type well surrounding the photodiode formed in a surface region of the N-type substrate and the sides and bottom of the element isolation region and the implanted isolation layer.

11. The method for manufacturing a solid-state imaging device according to claim 9,
wherein the solid-state imaging device has a structure in which multiple pixels are included in one cell, and
in the step of implanting an impurity into a sidewall of the trench formed around the photodiode included in each pixel, the impurity is implanted from a direction including a horizontal direction component perpendicular to the sidewall of the trench.

12. The method for manufacturing a solid-state imaging device according to claim 11,
wherein the sidewall of the trench comprises a portion that is neither vertical or horizontal relative to the photodiode, and
the impurity is implanted from multiple directions including a horizontal direction component perpendicular to the sidewall of the trench.
